(19) United States
(12) Patent Application Publication
(10) Pub. No.: US 2026/0043852 A1
(43) Pub. Date: Feb. 12, 2026

(54) MASS PRODUCTION INSPECTION DEVICE AND METHOD FOR ENERGY STORAGE SYSTEM

(71) Applicant: SAMSUNG SDI CO., LTD., Yongin-si (KR)

(72) Inventors: Ji Won YOO, Suwon-si (KR); Tae Hyoung LA, Suwon-si (KR); Gi Chan HWANG, Suwon-si (KR)

(21) Appl. No.: 19/293,062

(22) Filed: Aug. 7, 2025

(30) Foreign Application Priority Data
Aug. 8, 2024 (KR) 10-2024-0106120

(51) Int. Cl. G01R 31/36; H01M 10/04; H01M 10/42; H01M 10/48

(52) U.S. Cl. CPC G01R 31/3648; H01M 10/04; H01M 10/425; H01M 10/4285; H01M 10/482; H01M 2010/4271

(57) ABSTRACT

The present disclosure relates to a mass production inspection device and method for an energy storage system (ESS) and is directed to reducing the time required for a mass production inspection without degrading reliability by improving a mass production inspection process for a digital input function of a control battery management system (BMS). A configuration for performing of a mass production inspection on a digital input function of each of digital input ports of the control BMS includes changing all the digital input ports to the same contact state when the control BMS enters the test mode.

### CROSS-REFERENCE TO RELATED APPLICATION

This application claims priority to and the benefit of Korean Patent Application No 10-2024-0106120, filed on Aug. 8, 2024, the disclosure of which is incorporated herein by reference in its entirety.

### BACKGROUND

### 1. Field of the Disclosure

The present disclosure relates to a technology for mass production inspection of an energy storage system (ESS).

### 2. Discussion of Related Art

In mass production of battery management system (BMS) products, an inspection is performed to check whether each component operates normally for hardware quality verification. This mass production inspection is performed by providing input values and verifying whether output values expected in a normal operating state are produced. A container-type BMS product includes a control BMS that, unlike other BMSs, is connected to a large number of external devices to monitor an internal state of a container and enable container-level control.

The control BMS requires a large number of contact signal receivers and, for example, processes a total of 23 digital input signals. This causes a production inspection to be time consuming. For example, in a mass production inspection device, each contact signal receiver must be individually switched to open and short to verify the operation thereof, and open and short signals require a minimum of 500 msec (chattering time) to operate. Thus, it takes at least one second to inspect one digital input port (excluding the time for verifying feedback via communications), and inspecting all 23 digital input ports takes at least 23 seconds.

To minimize inspection time, in a conventional method, all 23 digital input port signals are processed simultaneously, with some ports reversed from short to open and the other ports from open to short for inspection. But this method lacks objectivity in determining whether each contact signal receiver individually performs input contact reception, which reduces the reliability of mass production inspection.

The information disclosed in this section is for enhancement of understanding of the background of the present disclosure and may contain information that does not constitute related (or prior) art.

### SUMMARY OF THE DISCLOSURE

The present disclosure is directed to providing a mass production inspection device and method for an energy storage system (ESS) that reduce the time required for a mass production inspection without degrading quality reliability during the mass production inspection by improving a mass production inspection process for a digital input function of a control battery management system (BMS) by entering a test mode during the mass production inspection.

However, objects that the present disclosure achieves are not limited to the objects expressly disclosed herein and other objects that are not described will be clearly understood by those skilled in the art from the following description.

According to an aspect of the present disclosure, there is provided a mass production inspection device for an ESS including a memory storing one or more instructions and a processor configured to execute the one or more instruction to perform a mass production inspection on the digital input function of a control BMS, wherein, the mass production inspection device is configured such that when the control BMS enters a test mode, the processor performs the mass production inspection on a digital input function of each of a plurality of digital input ports of the control BMS, with all the digital input ports being in a same contact state.

According to a further aspect of the present disclosure, there is provided a mass production inspection method for an energy storage system by using a processor executing instructions stored in a memory, the method including changing all of a plurality of digital input ports of a control battery management system to a same contact state when the control battery management system enters a test mode, and performing a mass production inspection on a digital input function of each of the digital input ports.

### BRIEF DESCRIPTION OF THE DRAWINGS

The drawings illustrate embodiments of the present disclosure and further describe aspects and features of the present disclosure together with the detailed description of the present disclosure. The present disclosure should not be construed as being limited to the drawings.

FIG. 1 is a block diagram of a mass production inspection device for an energy storage system (ESS) according to an embodiment of the present disclosure;

FIGS. 2 and 3 show examples for comparing a conventional inspection specification and an inspection specification of the present disclosure; and

FIGS. 4 and 5 are flowcharts for a mass production inspection method for an ESS according to an embodiment of the present disclosure.

### DETAILED DESCRIPTION OF EXEMPLARY EMBODIMENTS

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure. ” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

When an arbitrary element is referred to as being disposed (or located or positioned) on the “above (or below)” or “on (or under)” a component, it may mean that the arbitrary element is placed in contact with the upper (or lower) surface of the component and may also mean that another component may be interposed between the component and any arbitrary element disposed (or located or positioned) on (or under) the component.

In addition, it will be understood that when an element is referred to as being “coupled,” “linked” or “connected” to another element, the elements may be directly “coupled,” “linked” or “connected” to each other, or an intervening element may be present therebetween, through which the element may be “coupled,” “linked” or “connected” to another element. In addition, when a part is referred to as being “electrically coupled” to another part, the part can be directly connected to another part or an intervening part may be present therebetween such that the part and another part are indirectly connected to each other.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

### 1. Mass Production Inspection Device for Energy Storage System (ESS)

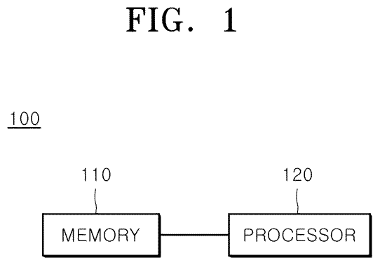

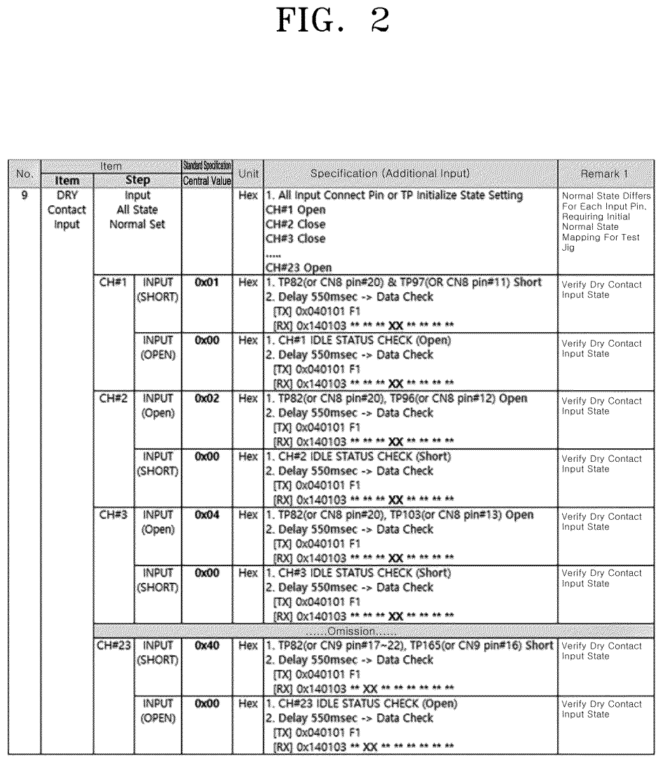

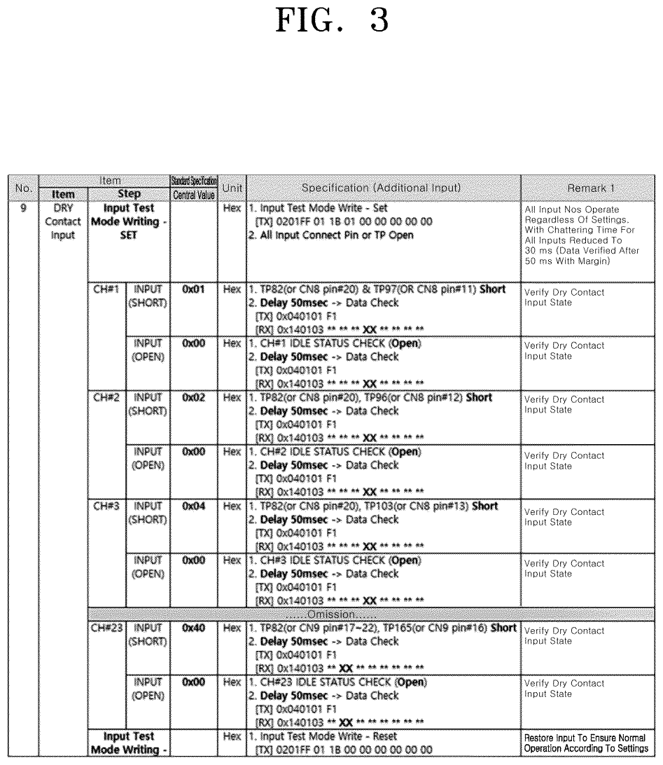

FIG. 1 is a block diagram of a mass production inspection device for an ESS according to an embodiment of the present disclosure, and FIGS. 2 and 3 show a conventional inspection specification and an inspection specification of the present disclosure, respectively.

Referring to FIG. 1, a mass production inspection device 100 for an ESS of the present embodiment may include a memory 110 and a processor 120.

At least one command executed by the processor 120 may be stored in the memory 110. The memory 110 may be implemented as a volatile storage medium and/or a non-volatile storage medium,. Specific examples of the memory include a read only memory (ROM) and/or a random access memory (RAM).

The memory 110 may store data required by the processor 120 during the process of performing mass production inspection for an ESS. The data may include setting information related to entering a test mode of a control battery management system (BMS), contact information of digital input ports of the control BMS, and time (chattering time) information required for operations related to contact state changes. Each data value may be predefined based on the specifications of the ESS and experimental results.

The processor 120, which is the primary component for performing the mass production inspection for an ESS, may be implemented as a central processing unit (CPU) or system on chip (SoC). The processor 120 may run an operating system or applications to control a plurality of hardware or software components connected to the processor 120 and perform various data processing and computations. The processor 120 may be configured to execute at least one command stored in the memory 110 and store data resulting from the execution in the memory 110.

When the control BMS enters the test mode, based on instructions stored in the memory 110 the processor 120 may perform a mass production inspection on a digital input function of each digital input port with all digital input ports of the control BMS changed to the same contact. That is, the processor 120 may perform the mass production inspection on the digital input function of each digital input port with all digital input ports of the control BMS changed to an A-contact (normally open).

The control BMS is connected to external devices (e.g., switches, air conditioning (HVAC) systems, cooling devices, fire detectors, and the like) through a plurality of digital input ports to process digital input signals within a container including a plurality of battery racks. Upon receiving a test mode entry command from the processor 120, the control BMS may enter the test mode to perform a mass production inspection on a digital input function of each of the digital input ports. When the control BMS enters the test mode, the processor 120 may forcibly adjust a time (chattering time) required for operations related to contact state changes of the digital input ports to a minimum time unit, and the control BMS may perform the mass production inspection on the digital input function of each digital input port with the adjusted minimum time unit.

The forcibly adjusted minimum time unit for the chattering time may be preset to 30 milliseconds (msec). That is, when the control BMS enters the test mode, the processor 120 may forcibly adjust the chattering time from, for example, the existing 500 msec to 30 msec and perform the mass production inspection on the digital input function of each digital input port in a 30 msec time.

Through a test jig of the mass production inspection device 100 for an ESS the processor 120 may sequentially command the control BMS to perform short and open operations for the digital input ports of mass production inspection device 100 and verify whether the short and open operations of the digital input ports are recognized as normal.

For example, when the processor 120 receives a short operation command for a digital input port #1 of the control BMS with all digital input ports changed to the A-contact (normally open), the processor 120 may switch the digital input port #1 of the control BMS to a short state. Then, after 50 msec (chattering time of 30 msec+a margin of 20 msec) has elapsed, the processor 120 may then verify whether the short operation of the corresponding digital input port #1 is normal. When it is verified to be normal, the processor 120 may switch the corresponding digital input port #1 to an open state, and, after 50 msec has elapsed, the processor 120 may verify that the open operation of the digital input port #1 is normal.

When digital input port #1 is verified to be normal, the processor 120 may switch a digital input port #2 of the control BMS to a short state. Then, after 50 msec has elapsed, the processor 120 may verify whether the short operation of the corresponding digital input port #2 is normal. When digital input port #2 is verified to be normal, the processor 120 may switch the corresponding digital input port #2 to an open state, and, after 50 msec has elapsed, the processor 120 may verify that the open operation of the corresponding digital input port #2 is normal.

By sequentially repeating this process up to a digital input port #n of the control BMS (where n is a natural number representing the number of the digital input ports provided in the control BMS), the processor 120 may continue to perform the mass production inspection for all of the remaining digital input ports.

As shown in FIGS. 2 and 3, according to an embodiment of the present disclosure, it may be confirmed that the time required for mass production inspection according to the present disclosure is reduced by a comparison of mass production inspection specifications. Referring to FIG. 2, in the case of the conventional inspection specification, a CH #1 (A-contact) and a CH #2 (B-contact) have different normal states,. Thus, jig contact states need to be controlled differently during inspection, which results in a minimum of 1.1 sec (550 msec*²) being needed to inspect one channel.

As described above, during a conventional mass production inspection, it is necessary to identify an initial operating state (an A-contact operation or a B-contact operation) of each of the 23 digital input ports to perform a digital input (DI) inspection. In the test jig, a different initial normal state is set for each DI channel, and, to inspect one DI channel, the channel is set to an event state. The, after waiting at least 500 msec (actually 550 msec with a margin), the control BMS recognizes the state of the contact signal receiver, and the control BMS reads this state through communication to verify whether the contact state has changed. The test jig then returns to the normal state and waits for at least 500 msec, after which the control BMS verifies that the contact state has returned to normal, thereby completing the inspection for one DI channel. Thus, inspecting one channel with this convention method, including the verification through communication, takes a minimum of 1.1 sec, and inspecting all 23 channels requires 25.3 seconds (23 digital inputs each taking 1.1 seconds to inspect).

Referring to FIG. 3, in the case of the inspection specification of the present disclosure, all channel contact states are unified as the A-contact (normally open) to ensure consistent jig contact control during inspection. As a result, inspecting one channel may take a minimum of 0.1 sec (50 msec*²). That is, according to the present embodiment, when the digital input test mode is set, all DI channels are switched to the A-contact (normally open), and the minimum time (chattering time) required for contact state changes is adjusted from 500 msec to 30 msec, thereby reducing inspection complexity and shortening the time required for inspection. In practice, even with a margin for verification through communication, the time required to inspect one DI channel is reduced from 1.1 sec to 0.1 sec (50 msec*² for open and short verification). Thus, the total inspection time for all 23 channels can be reduced to 2.3 sec, thereby achieving an inspection speed that is 11 times faster than with the conventional method.

### 2. Mass Production Inspection Method for ESS

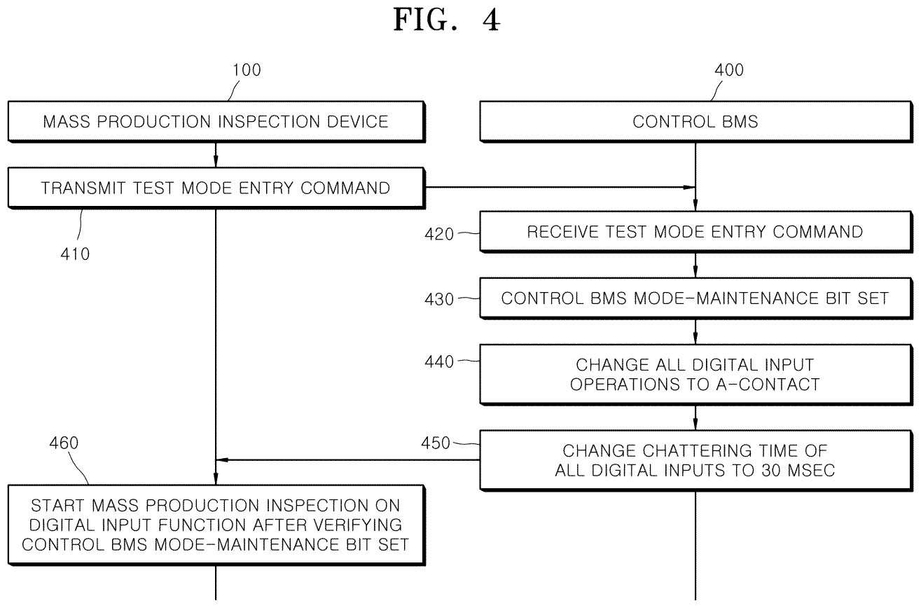

Before describing a mass production inspection method for an ESS according to the present embodiment, a method of setting a digital input test mode will be first described. FIG. 4 is a flowchart of a method of setting the digital input test mode in the mass production inspection method for an ESS according to an embodiment of the present disclosure. The method of setting the digital input test mode will be described with reference to FIG. 4, but descriptions that are the same as those above will be omitted.

First, the mass production inspection device 100 transmits a test mode entry command to a control BMS 400 in step 410. The control BMS 400 then receives the test mode entry command in step 420, and the control BMS 400 performs a control BMS mode-maintenance bit set step 430.

Subsequently, the control BMS 400 changes all digital input operations to an A-contact (normally open) in step 440. Thereafter, the control BMS 400 changes the chattering time of all digital inputs to 30 msec in step 450.

Subsequently, the mass production inspection device 100 starts a mass production inspection on a digital input function after verifying the control BMS mode-maintenance bit set in step 460.

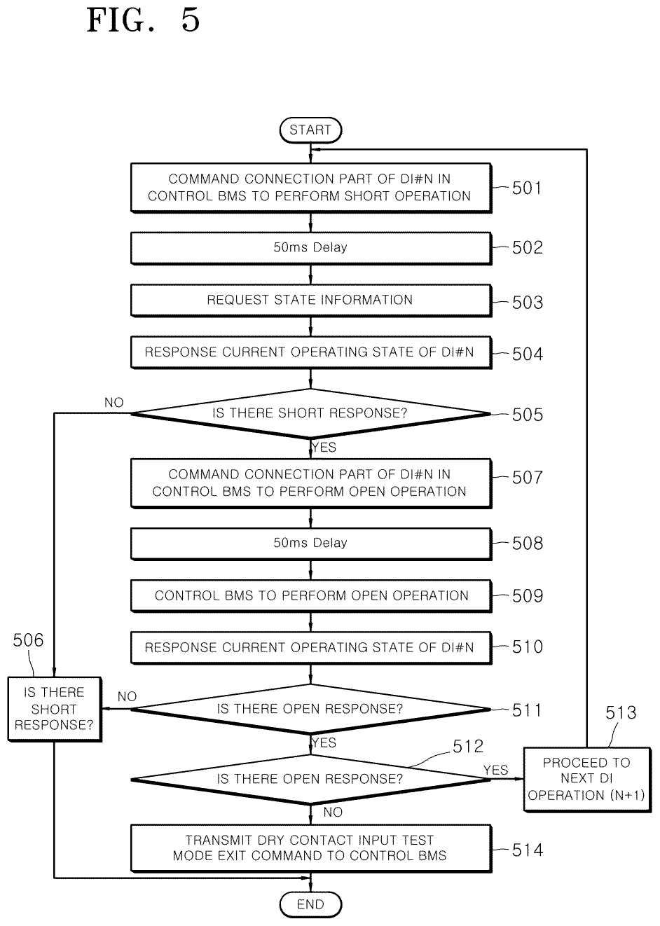

FIG. 5 is a flowchart of a mass production inspection method for an ESS according to an embodiment of the present disclosure. Here, the mass production inspection method for an ESS may be performed when the control BMS enters a test mode. The process in which the control BMS enters the test mode is described above with reference to FIG. 1.

Referring to FIGS. 1 and 5, in operation 501, the processor 120 issues a short operation command to a connection part of a DI #n (digital input port #n, where n is a natural number starting from 1) of the control BMS. The short operation command causes the connection part of DI #n to change to a short state.

Next, in operation 502, the processor 120 introduces a 50 ms delay for chattering following the short operation of the connection part of the DI #n, and in operation 503, the processor 120 requests state information from the control BMS to verify whether the short operation of the DI #n in the control BMS is normal.

Next, in operation 505,, after receiving a response from the control BMS regarding the current operating state of the DI #n in operation 504, the processor determines whether the current operating state of the DI #n indicates a short response. When the determination result indicates that it is not a short response (a “NO” direction of 505), the processor 120 outputs a mass production inspection failure in operation 506 and terminates the procedure.

On the other hand, when the determination result indicates a short response (a “YES” direction of 505), in operation 507 the processor 120 issues an open operation command to the connection part of the DI #n in the control BMS to change the connection part of the DI #n to an open state.

In operation 508, the processor 120 introduces a 50 ms delay for chattering following the open operation of the connection part of the DI #n, and in operation 509 the processor 120 requests state information from the control BMS to verify whether the open operation of the DI #n in the control BMS is normal.

In operation 511, after receiving a response from the control BMS regarding the current operating state of the DI #n in operation 510 the processor 120 determines whether the current operating state of the DI #n indicates an open response. When it is determined that there is not an open response (the “NO” direction of 511), the processor 120 outputs the mass production inspection failure in operation 506 and terminates the procedure.

On the other hand, when the determination result indicates an open response (the “YES” direction of 511), in operation 512 the processor 120 checks whether there is a next DI. When there is a next DI (the “YES” direction of 512), the processor 120 proceeds to the next DI operation in operation 513 (n=n+1) and returns to operation 501 to repeat the previous operations 501 to 512. However, when there is no next DI (the “NO” direction of 512), in operation 514 the processor 120 transmits a dry contact input test mode exit command to the control BMS to exit the test mode of the control BMS and terminate the corresponding mass production inspection.

As described above, according to the present disclosure, the time required for a mass production inspection can be reduced without degrading reliability during the mass production inspection by improving a mass production inspection process for a digital input function of a control BMS through entering a test mode during the mass production inspection.

Further, according to the present disclosure, when the control BMS enters the test mode, all digital input ports of the control BMS are switched to an A-contact (normally open). The minimum time (chattering time) required for contact state changes is adjusted (e.g., from 500 msec to 30 msec), thereby reducing the complexity of the mass production inspection and shortening the time required for inspection.

The embodiments described herein may be implemented, for example, as a method or process, a device, a software program, a data stream, or a signal. Although discussed in the context of a single type of implementation (for example, discussed only as a method), features discussed herein may also be implemented in other forms (for example, a device or a program). The device may be implemented by suitable hardware, software, firmware, and the like. The method may be implemented on a device, such as a processor that generally refers to a processing device including a computer, a microprocessor, an integrated circuit, a programmable logic device, etc. The processor includes a communication device such as a computer, a cell phone, a personal digital assistant (PDA), and other devices that facilitate communication of information between the device and end-users.

According to the present disclosure, the time required for a mass production inspection can be reduced without degrading reliability during the mass production inspection by improving a mass production inspection process for a digital input function of a control BMS through entering a test mode during the mass production inspection.

Further, according to the present disclosure, when the control BMS enters the test mode, all digital input ports of the control BMS are switched to an A-contact (normally open). The minimum time (chattering time) required for contact state changes is forcibly adjusted (e.g., from 500 msec to 30 msec), thereby reducing the complexity of the mass production inspection and shortening the time required for inspection.

However, effects that can be achieved through the present disclosure are not limited to the above-described effects and other effects that are not described may be clearly understood by those skilled in the art from the detailed description.

Although the present disclosure has been described with reference to embodiments and drawings illustrating aspects thereof, the present disclosure is not limited thereto. Various modifications and variations can be made by a person skilled in the art to which the present disclosure belongs within the scope of the technical spirit of the present disclosure.

What is claimed is:

1. A mass production inspection device for an energy storage system, the mass production inspection device comprising:
a memory configured to store one or more instructions; and
a processor configured to execute the one or more instructions to perform a mass production inspection on a digital input function of a control battery management system,
wherein the mass production inspection device is configured such that when the control battery management system enters a test mode the processor performs the mass production inspection on a digital input function of each of a plurality of digital input ports of the control battery management system with all the digital input ports being in a same contact state.

2. The mass production inspection device of claim 1, wherein the processor performs the mass production inspection on the digital input function of each of the digital input ports with all the digital input ports of the control battery management system changed to an A-contact state.

3. The mass production inspection device claim 1, wherein, when the control battery management system enters the test mode, the processor adjusts a chattering time that is required for operations related to contact state changes of the digital input ports and the processor performs the mass production inspection on the digital input function of each of the digital input ports with the adjusted chattering time.

4. The mass production inspection device of claim 3, wherein the processor reduces a current chattering time when adjusting the chattering time.

5. The mass production inspection device of claim 1, wherein the processor sequentially commands the control battery management system through a test jig of the mass production inspection device to perform short and open operations for the digital input ports, and the processor verifies through the control battery management system whether the short and open operations of the digital input ports are recognized as normal.

6. The mass production inspection device of claim 5, wherein, when commanding the control battery management system to perform the short operations for each of the digital input ports, the processor verifies through the control battery management system whether the short operation of the digital input port is recognized as normal after a minimum chattering time has elapsed.

7. The mass production inspection device of claim 5, wherein, when commanding the control battery management system to perform the open operation for each of the digital inputs port, the processor verifies through the control battery management system whether the open operation of the digital input port has been recognized as normal after a minimum chattering time has elapsed.

8. The mass production inspection device of claim 5, wherein, when the verification result indicates that the short and open operations for a digital input port of the digital input ports is recognized as normal, the processor determines the operating state of the digital input port as being normal and continues to perform the mass production inspection for others of the digital input ports.

9. The mass production inspection device of claim 1, wherein the control battery management system is connected to external devices through the digital input ports to process digital input signals within a container including a plurality of battery racks, and
wherein the mass production inspection device enters the test mode to perform the mass production inspection on the digital input function of each of the digital input ports upon receiving a test mode entry command from the processor.

10. A mass production inspection method for an energy storage system by using a processor executing instructions stored in a memory, the method comprising:
changing all of a plurality of digital input ports of a control battery management system to a same contact state when the control battery management system enters a test mode; and
performing a mass production inspection on a digital input function of each of the digital input ports.

11. The mass production inspection method of claim 10, wherein the performing of the mass production inspection includes performing the mass production inspection on the digital input function of each of the digital input ports, with all the digital input ports of the control battery management system changed to an A-contact state.

12. The mass production inspection method of claim 10, wherein the performing of the mass production inspection comprises:
adjusting a chattering time that is a time required for operations related to contact state changes of the digital input ports when the control battery management system enters the test mode; and
performing the mass production inspection on the digital input function of each of the digital input ports with the adjusted chattering time.

13. The mass production inspection method of claim 12, wherein adjusting of the chattering time comprises reducing a current chattering time.

14. The mass production inspection method of claim 10, wherein the digital input ports are part of an energy storage system, and
wherein the performing of the mass production inspection comprises:
sequentially commanding the control battery management system through a test jig of a mass production inspection device to perform short and open operations for the digital input ports; and
verifying, through the control battery management system, whether the short and open operations of the digital input ports are normal.

15. The mass production inspection method of claim 14, wherein the performing of the mass production inspection includes, when commanding the control battery management system to perform a short operation for a digital input port of the digital input ports, verifying through the control battery management system whether the short operation of the digital input port is normal after a minimum chattering time has elapsed.

16. The mass production inspection method of claim 14, wherein the performing of the mass production inspection includes, when commanding the control battery management system to perform an open operation for a digital input port of the digital input ports, verifying, through the control battery management system whether the open operation of the digital input port is normal after a minimum chattering time has elapsed.

17. The mass production inspection method of claim 14, wherein the performing of the mass production inspection further includes, when the verification result indicates that the short and open operations of a digital input port of the digital input ports is normal, determining an operating state of the digital input port as being normal and continuing to perform the mass production inspection for others of the digital input ports.

18. The mass production inspection method of claim 10, wherein the control battery management system is connected external devices through the plurality of digital input ports to process digital input signals within a container including a plurality of battery racks, and the control battery management system enters the test mode to perform the mass production inspection on the digital input function of each of the digital input ports upon receiving a test mode entry command from the processor.
